(19) United States
(12) Patent Application Publication
(10) Pub. No.: US 2016/0091308 A1
(43) Pub. Date: Mar. 31, 2016

(54) MICROELECTROMECHANICAL SYSTEMS (MEMS) ACOUSTIC SENSOR-BASED GESTURE RECOGNITION

(71) Applicant: INVENSENSE, INC., San Jose, CA (US)

(72) Inventor: Omid Oliaei, Sunnyvale, CA (US)

(21) Appl. No.: 14/503,012

(22) Filed: Sep. 30, 2014

(51) Int. Cl. G01B 17/00; B81B 3/00

(52) U.S. Cl. CPC G01B 17/00; B81B 3/0021; B81B 2201/0257

(57) ABSTRACT

Microelectromechanical systems (MEMS) acoustic sensor-based gesture recognition associated with detecting gestures is described. Provided implementations can comprise MEMS acoustic sensor elements that receive signals reflected off an object. A time sequence associated with each of the MEMS acoustic sensor elements detecting proximity of the object is determined. A gesture is identified based on the time sequence. Functions of a device are controlled according to the gesture.

### TECHNICAL FIELD

The subject disclosure relates to microelectromechanical systems (MEMS), more particularly, MEMS acoustic sensor-based gesture recognition.

### BACKGROUND

Conventionally, motion sensors are used to detect or sense a motion via motion sensors. Such motion sensors are used to detect when an object, such as a hand, passes through an infrared (IR) beam (or field). Other motion sensors can include a camera that can detect motion or recognize images. To enable motion detection, motion sensors utilize IR beam emitter and an IR receiver or detector. The emitted IR signal will reflect of an external object (if present). Some systems utilize multiple IR beams that can communicate to detect motion. If a reflected IR signal is received by an IR receiver, such motion sensors determine that an object is in motion.

IR motion sensors can be optimized for different objects. For example, the cellular phone industry uses IR proximity sensors to detect the movement of a user, specifically the user's hand or fingers. Traditional motion sensors often utilize in the hundreds of micro amps on average. Further, these motion sensors are subject to inaccuracies due to light reflections or dispersions, such as due to contaminants on the surface of a device. Additionally, the operation of such motion sensors is adversely affected by ambient light, temperature variation, texture of objects, color of objects, and other factors.

It is thus desired to provide MEMS proximity sensors that improve upon these and various other deficiencies. The above-described deficiencies of MEMS proximity sensors are merely intended to provide an overview of some of the problems of conventional implementations, and are not intended to be exhaustive. Other problems with conventional implementations and techniques and corresponding benefits of the various aspects described herein may become apparent upon review of the following description.

### SUMMARY

The following presents a simplified summary of the specification to provide a basic understanding of some aspects of the specification. This summary is not an extensive overview of the specification. It is intended to neither identify key or critical elements of the specification nor delineate any scope particular to any embodiments of the specification, or any scope of the claims. Its sole purpose is to present some concepts of the specification in a simplified form as a prelude to the more detailed description that is presented later.

In a non-limiting example, a system comprising a plurality of MEMS acoustic sensor detects gestures from a user, such as when a user waves a hand or other object. Each MEMS acoustic sensor can detect when an object is within a determined proximity or distance of the MEMS acoustic sensors. The system determines entry times and exit times associated with the object being detected in fields of detection of each of the MEMS acoustic sensors. The entry times and exit times form a time sequence. The system detects or identifies the gesture based on the time sequence and performs operations based on the gesture.

Moreover, an exemplary method for detecting a gesture using a device having MEMS acoustic sensors and configured is described. The method can comprise generating acoustic signals, via a transmitter, for reflection off an object. In another aspect, the method can comprise receiving signals, via a plurality of receivers, reflected from the object. Times associated with each of the receivers receiving the signals then not receiving the signals are determined. A gesture is identified based on the times.

The following description and the drawings set forth certain illustrative aspects of the specification. These aspects are indicative, however, of but a few of the various ways in which the principles of the specification may be employed. Other advantages and novel features of the specification will become apparent from the following detailed description of the specification when considered in conjunction with the drawings.

### BRIEF DESCRIPTION OF THE DRAWINGS

Numerous aspects, embodiments, objects and advantages of the present invention will be apparent upon consideration of the following detailed description, taken in conjunction with the accompanying drawings, in which like reference characters refer to like parts throughout, and in which:

FIG. 1 depicts a non-limiting schematic block diagram of a microelectromechanical systems (MEMS) acoustic sensor-based gesture recognition system, according to various non-limiting aspects of the subject disclosure;

FIG. 2 depicts a further non-limiting cross sectional diagram of a MEMS acoustic sensor-based gesture recognition system, according to various non-limiting aspects of the subject disclosure;

FIG. 3 depicts a further non-limiting schematic diagram of an exemplary MEMS acoustic sensor-based gesture recognition system comprising a sensor fusion component, according to other non-limiting aspects of the subject disclosure;

FIG. 4 depicts a further non-limiting schematic diagram of a MEMS acoustic sensor-based gesture recognition system recognizing a horizontal swipe, according to various non-limiting aspects of the subject disclosure;

FIG. 5 depicts a further non-limiting schematic diagram of MEMS acoustic sensor-based gesture recognition system recognizing a vertical swipe, according to various non-limiting aspects of the subject disclosure;

FIG. 6 depicts a further non-limiting schematic diagram of an exemplary MEMS acoustic sensor-based gesture recognition system comprising a pattern component, according to other non-limiting aspects of the subject disclosure;

FIG. 7 depicts non-limiting exemplary graphs associated with a MEMS acoustic sensor-based gesture recognition system, according to various non-limiting aspects of the subject disclosure;

FIG. 8 depicts non-limiting exemplary graphs associated with a MEMS acoustic sensor-based gesture recognition system detecting push and pull gestures, according to various non-limiting aspects of the subject disclosure;

FIG. 9 depicts an exemplary flowchart of non-limiting methods associated with a MEMS acoustic sensor-based gesture recognition system comprising a first, a second, and a third acoustic sensor, according to various non-limiting aspects of the disclosed subject matter;

FIG. 10 depicts an exemplary flowchart of non-limiting methods associated with a MEMS acoustic sensor-based gesture recognition system comprising generating an instruction for control of a device, according to various non-limiting aspects of the disclosed subject matter;

FIG. 11 depicts an exemplary flowchart of non-limiting methods associated with a MEMS acoustic sensor-based gesture recognition system comprising recognizing a user defined gesture, according to various non-limiting aspects of the disclosed subject matter;

FIG. 12 depicts an example schematic block diagram for a computing environment in accordance with certain embodiments of this disclosure; and

FIG. 13 depicts an example block diagram of a computer network operable to execute certain embodiments of this disclosure.

### DETAILED DESCRIPTION

### Overview

While a brief overview is provided, certain aspects of the subject disclosure are described or depicted herein for the purposes of illustration and not limitation. Thus, variations of the disclosed embodiments as suggested by the disclosed apparatuses, systems and methodologies are intended to be encompassed within the scope of the subject matter disclosed herein. For example, the various embodiments of the apparatuses, techniques and methods of the subject disclosure are described in the context of MEMS acoustic sensors. However, as further detailed below, various exemplary implementations can be applied to other areas of MEMS sensor design and packaging, without departing from the subject matter described herein.

As used herein, the terms MEMS proximity sensor(s), MEMS microphone(s), MEMS acoustic sensor(s), MEMS audio sensor(s), and the like are used interchangeably unless context warrants a particular distinction among such terms. For instance, the terms can refer to MEMS devices or components that can measure a proximity, determine acoustic characteristics, generate acoustic signals, or the like.

Additionally, terms such as “at the same time,” “common time,” “simultaneous,” “simultaneously,” “concurrently,” “substantially simultaneously,” “immediate,” and the like are employed interchangeably throughout, unless context warrants particular distinctions among the terms. It should be appreciated that such terms can refer to times relative to each other and may not refer to an exactly simultaneously action(s). For example, system limitations (e.g., download speed, processor speed, memory access speed, etc.) can account for delays or unsynchronized actions. In other embodiments, such terms can refer to acts or actions occurring within a period that does not exceed a defined threshold amount of time.

Traditional gesture detection devices typically involve IR sensors, light sensors, or cameras. Devices using IR sensors generate an IR beam or radiation, determine positions, and detect a reflection of the generated IR beam. Devices using cameras utilize complicated image recognition functions. Such devices require constant power consumption when detecting gestures. Further, traditional gesture detecting devices can be negatively affected by light, temperature, characteristics of objects/surfaces, and the like. In addition, such devices often require complex control algorithms, specialized components, and consume greater amounts of power compared to embodiments described herein.

The systems and methods of the present invention can operate at very low power levels. Further, systems and methods of the present invention may be ideal for the always-on concept in which gesture detection is always on. Furthermore, various embodiments described herein can provide robust gesture detection. For instance, systems and methods may not be or affected, or may be minimally affected, by light, temperature, characteristics of objects/surfaces, and the like.

To these and/or related ends, various aspects of MEMS acoustic sensor-based gesture recognition systems, methods, and apparatuses that detect gestures are described herein. For instance, exemplary implementations can provide a MEMS acoustic sensor-based gesture recognition system that comprises an array of acoustic sensors or microphones. In an aspect, a component of the system (e.g., a MEMS microphone, a speaker, etc.) can generate an acoustic signal. The array of acoustic sensors can receive acoustic signals (e.g., ultrasonic signals) reflected off an object (e.g., a user's hand). Each acoustic sensor can be associated with an entry time corresponding to detection of the object in a threshold proximity and an exit time corresponding to the object no longer being detected within the threshold proximity (e.g., exiting the proximity threshold range). Based on the entry and exit times, the system can determine a time sequence associated with the array of acoustic sensors and a gesture can be recognized based on the time sequence.

As an example, a MEMS acoustic sensor-based gesture recognition system can comprise a smart phone. A user can interact with the smart phone to provide a gesture. For instance, the user can wave or swipe a hand sufficiently close to the smart phone (e.g., within threshold range of detection, such as 15 cm, etc.). As the user's hand waves, the hand will pass through detection fields associated with each MEMS acoustic sensor, at different times. Based on these times, a time sequence can be determined and a gesture can be identified based on the time sequence. The gesture can be utilized to control functions of the smart phone, such as, for example, unlocking the smart phone, waking up the smart phone, flipping a page of a digital media item (e.g., digital book, magazine, periodical, etc.), scrolling, navigating between screens, or the like.

In non-limiting implementations, a MEMS acoustic sensor-based gesture recognition system can determine whether an object(s) is within a threshold distance (e.g., close proximity) of the system or whether the object(s) are outside of the threshold distance. As a non-limiting example, exemplary embodiments of a MEMS acoustic sensor-based gesture recognition system can comprise acoustic sensors that can generate acoustic signals and/or receive acoustic signals. The acoustic sensors can alternate between a generating state and a listening state to facilitate proximity detections. In other non-limiting examples, the MEMS acoustic sensor-based gesture recognition system can comprise acoustic sensors designated for one or more of receiving signals or generating signals.

Furthermore, a controller can control various circuitry, components, and the like, to facilitate proximity detection. For instance, the controller can comprise a processing device (e.g., computer processor) that controls generation of signals, modes of operation and the like. Additionally, embodiments disclosed herein may be comprised in larger systems or apparatuses. For instance, aspects of this disclosure can be employed in smart televisions, smart phones or other cellular phones, wearables (e.g., watches, headphones, etc.), tablet computers, electronic reader devices (i.e., e-readers), laptop computers, desktop computers, monitors, digital recording devices, appliances, home electronics, handheld gaming devices, remote controllers (e.g., video game controllers, television controllers, etc.), automotive devices, personal electronic equipment, medical devices, industrial systems, bathroom fixtures (e.g., faucets, toilets, hand dryers, etc.), printing devices, cameras, and various other devices or fields.

Aspects of systems, apparatuses or processes explained in this disclosure can constitute machine-executable components embodied within machine(s), hardware components, or hardware components in combination with machine executable components, e.g., embodied in one or more computer readable mediums (or media) associated with one or more machines. Such components, when executed by the one or more machines, e.g., computer(s), computing device(s), virtual machine(s), etc., can cause the machine(s) to perform the operations described. While the various components are illustrated as separate components, it is noted that the various components can be comprised of one or more other components. Further, it is noted that the embodiments can comprise additional components not shown for sake of brevity. Additionally, various aspects described herein may be performed by one device or two or more devices in communication with each other.

To that end, the one or more processors can execute code instructions stored in memory, for example, volatile memory and/or nonvolatile memory. By way of illustration, and not limitation, nonvolatile memory can include read only memory (ROM), programmable ROM (PROM), electrically programmable ROM (EPROM), electrically erasable PROM (EEPROM), or flash memory. Volatile memory can include random access memory (RAM), which acts as external cache memory. By way of illustration and not limitation, RAM is available in many forms such as static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). The memory (e.g., data stores, databases) of the subject systems and methods is intended to comprise, without being limited to, these and any other suitable types of memory.

As it employed in the subject specification, the term “processor” can refer to substantially any computing processing unit or device comprising, but not limited to comprising, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Processors can exploit nano-scale architectures such as, but not limited to, molecular and quantum-dot based transistors, switches and gates, in order to optimize space usage or enhance performance of user equipment. A processor may also be implemented as a combination of computing processing units.

### Exemplary Embodiments

Various aspects or features of the subject disclosure are described with reference to the drawings, wherein like reference numerals are used to refer to like elements throughout. In this specification, numerous specific details are set forth in order to provide a thorough understanding of the subject disclosure. It should be understood, however, that the certain aspects of disclosure may be practiced without these specific details, or with other methods, components, parameters, etc. In other instances, well-known structures and devices are shown in block diagram form to facilitate description and illustration of the various embodiments.

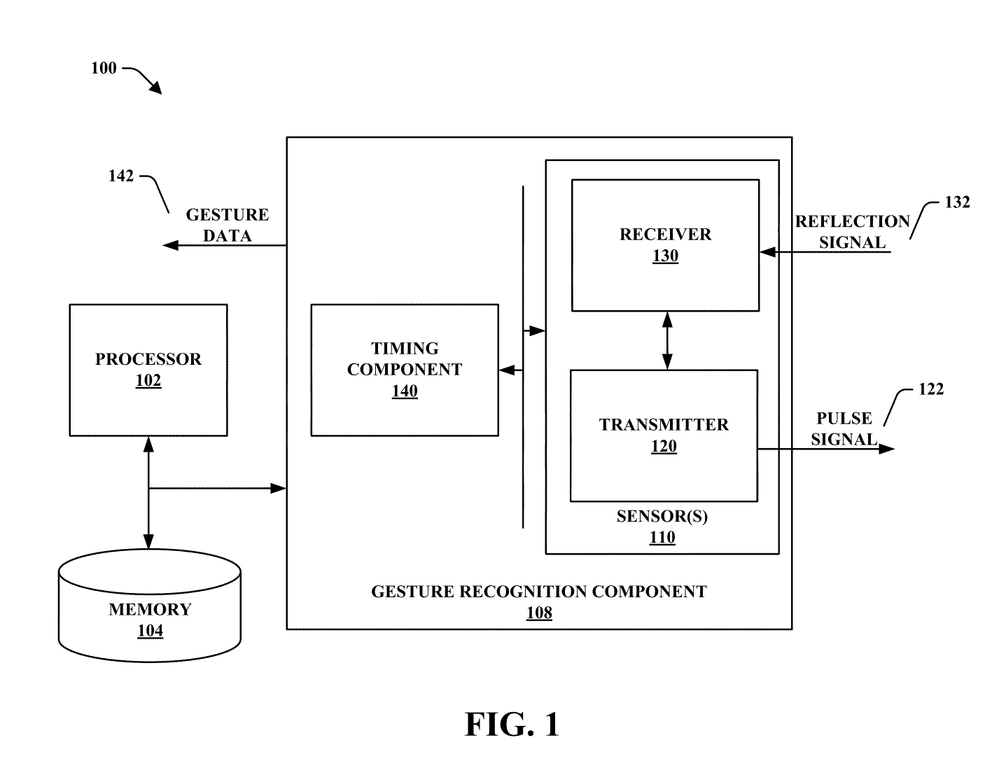

Accordingly, FIG. 1 depicts non-limiting block diagrams of a system 100 capable of gesture recognition, according to various non-limiting aspects of the subject disclosure. It is to be appreciated that system 100 can be used in connection with implementing one or more systems or components shown and described in connection with other figures disclosed herein. It is noted that all or some aspects of system 100 can be comprised in larger systems such as servers, computing devices, smart phones, tablet computers, laptop computers, personal digital assistants, set top box, computer monitors, remote controllers, headphones, and the like. Further, it is noted that the embodiments can comprise additional components not shown for sake of brevity. Additionally, various aspects described herein may be performed by one device or two or more devices in communication with each other.

System 100 can include a memory 104 that stores computer executable components and a processor 102 that executes computer executable components stored in the memory 104. It is to be appreciated that system 100 can be used in connection with implementing one or more of the systems or components shown and described in connection with other figures disclosed herein. Gesture recognition component 108 can comprise a sensor(s) 110 (which can generate and/or received pulse signals) and a timing component 140 (which can determine a time sequence associated with the sensors 110 detecting an object).

It is noted that sensors 110 can comprise one or more sensing elements. Such sensing elements can include membranes, diaphragms, or other elements capable of sensing and/or generating pulse signals. For instance, one or more membranes of sensors 110 can be excited to transmit a pulse signal. In another aspect, a plurality of membranes of sensors 110 can receive pulse signals that induce movement of the one or more membranes. Furthermore, such sensing elements may be embodied within or coupled to hardware, such as a single integrated circuit (IC) chip, multiple ICs, an ASIC, or the like. In various aspects, an ASIC can include or can be coupled to a processor, transmitter 120, and receivers 130.

As depicted, sensors 110 can comprise a transmitter(s) 120 and receivers 130. Transmitter(s) 120 and receivers 130 can comprise audio sensors, such as a MEMS microphone. For instance, transmitter 120 can comprise a MEMS microphone configured to generate pulse signal 122, which can be a modulated sinusoidal wave signals and can be of a determined frequency. Pulse signals 122 can be an audio signal and/or ultrasonic signal for proximity detection, distance measurements, and/or to execute various other actions. Likewise, receivers 130 can comprise MEMS microphones configured to receive a pulse signal (e.g., reflected signal 132) for proximity detection, distance measurements, and/or to execute various other actions. It is noted that audio sensors can be omni-directional (e.g., signals coming from all directions can be received), unidirectional (e.g., signals coming from less than all directions can be received), or the like. However, in some embodiments, receivers 130 can be unidirectional and positioned to determine a presence or proximity of an object in a determined direction as described in various embodiments disclosed herein.

Likewise, the one or more audio sensors can be reciprocal, that is, transmitter 120 and receivers 130 can each act as both a transmitter and a receiver. For instance, the audio sensors can be selectively or programmably configured to perform a specific function. It is noted that various combination of different types of MEMS microphones can be utilized as long as a MEMS microphone can generate the pulse signal 122 and other MEMS microphones (or the same MEMS microphone) can receive reflected signal 132 from the desired direction(s) for determining proximity. For example, the various acoustic sensors of system 100 (e.g., receivers 130, transmitter 120, etc.) can be of different designs and/or sensitivities. For instance, the acoustic sensors can apply different frequency response transfer functions during signal processing. In an aspect, detection data of the various acoustic sensors are not combined and gesture recognition is not adversely affected by the differences in the sensors. It is further noted that various embodiments disclosed herein can utilize raw proximity data and no position data or other data is needed to facilitate gesture recognition. This and other aspects can contribute to the robustness of the various embodiments.

In various other aspects, system 100 can comprise other components or devices that are capable of generating a signal. For example, system 100 may comprise one or more speakers that can generate acoustic signals (e.g., pulse signal 122). Acoustic signals can be virtually any frequency including signals in the audio spectrum, ultrasonic spectrum, and the like. For instance, pulse signal 122 can be an ultrasound pulse outside of the human hearing spectrum. In other embodiments, the pulse signal can be of a frequency such that animals or a particular type of animal (e.g., dog) cannot hear the acoustic signal. Frequencies in the human audible ranges can be utilized, however, as a practical matter, humans may find an audible signal annoying or interfering (e.g., such as with a telephone conversation). Likewise, frequencies in the canine audible ranges, for example, can be utilized but certain applications may not be practically suited for such frequencies. For example, an electronic device emitting an audible signal in the canine audible ranges may be more prone to damage from canines or may irritate such canines. Accordingly, while the various embodiments described herein refer to pulse signals, ultrasound signals, acoustic signals, and/or audio signals, such embodiments may utilize any signal that acoustic sensors (e.g., MEMS microphones, etc.) can receive.

In various embodiments, transmitter(s) 120 can be configured to generate ultrasound pulse signals at frequencies determined according to properties of sensor(s) 110, such as sensitivity, power consumption, and the like. For instance, each of receiver(s) 130 can have different ranges of sensitivity. Frequencies within a given range may be associated with low sensitivity of one or more receiver(s) 130, while frequencies of a different range may be associated with higher sensitivity of one or more receiver(s) 130 and transmitter(s) 120 can be configured to generate signals in a desired range based on the sensitivity of receiver(s) 130. In another aspect, certain frequency ranges can be associated with different power consumptions. For example, low frequencies can be associated with a first power consumption by sensor 110 (e.g., via transmitter 120, receiver 130, or both) and high frequencies can be associated with a second power consumption. In at least one embodiment, system 100 can generate (e.g., transmit by transmitter 120) signals of about twenty two kilohertz (kHz) up to about 80-85 kHz. While pulse signals are generally referred to herein and select ranges may be referenced, it is noted that a generated signal can be various other types of signals having various properties. Moreover, each receiver(s) 130 can be configured to detect frequencies in a unique, with respect other receiver(s) 130 ranges. In another aspect, each of receiver(s) 130 can be configured to detect frequencies is in a common range.

In embodiments, receiver(s) 130 can determine a proximity or detect an object based on determining a proximity. For instance, one or more receiver(s) 130 can receive reflected signals generated by transmitter 120. Based on the received signals, the one or more receiver(s) 130 can determine a proximity of an object. Determining proximity can comprise counting a number of pulses, such as received pulses, clock pulses, or the like. For example, transmitter 120 can generate pulse signal 122. If a user's hand is currently within a threshold distance from one or more receiver(s) 130, the pulse signal can be reflected or refracted back to the one or more receiver(s) 130. Receiver 130 can receive reflected signal 132 and monitor a number of received pulses. In an aspect, if a pulse count is above a threshold number (e.g., a number, percentage, etc.), then it is determined that user's hand (or any other object) is in a close vicinity, such as within ten mm, ten cm, etc. It is noted that detection of the object can utilize a “time of flight” process that measures a time between a pulse being transmitted and the pulse being received (e.g., as reflected signal 132). In an aspect, the measured time(s) can be utilized to determine a proximity, distance, speed, etc. As another example, receiver 130 can determine proximity, distance, and/or speed based on parameters associated with reflected signal 132. For example, receivers 130 can determine a proximity based on a modulated signal and/or can be encoded to facilitate detection of the reflected signal or alter (e.g., enhance) the detection accuracy. For instance, a mobile device can be configured to determine a proximity based on modulation of reflected signal 132. While modulation may depend on the type of surface that reflects signals, some embodiments may be designed to reflect off a specific type of surface (e.g., user's hand, a specific device (e.g., stylus), or the like. As such, detection can be calibrated based on reflection off a specific surface (e.g., user's hand(s), gloved hand(s), a stylus, etc.). In another aspect, receivers 130 can be configured to determine a proximity based on a signal energy parameter As such, receivers 130 can be calibrated according to a modulation scheme and/or a signal energy scheme. In another aspect, detection component receivers 130 can utilize auto-correlation processes, cross-correlation processes, demodulation processes, or other processes to facilitate determining a proximity.

A threshold number of pulses can be associated with a threshold distance. For example, one or more receiver(s) 130 can be calibrated such that a number of received pulses outside of a threshold range of pulses can be associated with a distance of an object described as far (e.g., over ten mm, ten cm, etc.). Likewise, if the number of pulses is within the threshold range of pulses, the distance can be described as near (e.g., within ten mm, ten cm). It is noted that the threshold number of pulses can be a predetermined number of pulses or can be dynamically determined, such as through user input or determined based on a calibration process. In various embodiments, the threshold number of pulses can be application specific and/or based on parameters of sensor(s) 110. For instance, a threshold range of pulses can be a first range for more sensitive sensors and a second range for less sensitive sensors. In another aspect, the threshold range of pulses can be different for applications requiring a closer threshold distance (e.g., 5 mm, 5 cm, etc.) than for applications requiring a relatively further threshold distance (e.g., 15 mm, 15 cm, etc.). For example, a mobile device may have a different threshold range than a desktop computer.

In another aspect, proximity can be determined in a binary fashion, where a proximity is either near or far. In other embodiments, proximity can be determined based on a relative distance, according to a different number of distances or proximities (e.g., near, intermediate, far). It is noted that other embodiments can utilize various nomenclatures and/or can determine distances (or ranges of distance) or estimate distances. In another aspect, the one or more receiver(s) 130 can determine directions associated with gestures, speed associated with gestures, or other parameters associated with the gestures, based on the proximity detection.

It is noted that each receiver of receivers 130 can be configured to detect disparate frequency ranges such that a single transmitter or multiple transmitters 120 can generate different pulse signals 122 at different frequencies for the specific receivers. In another aspect, each receiver of receivers 130 can be a MEMS microphone and can be configured to be unidirectional with regards to transmitting and/or receiving. In such embodiments, each MEMS microphone can be configured to transmit and receive their own signals. In some embodiments, one or more omni-directional transmitters 120 can generate pulse signals and receivers 130 may be unidirectional with respect to receiving. Utilizing an omni-directional transmitter 120 in combination with unidirectional receivers 130 can enable a single transmitter 120 to generate one signal that can be received by each receiver of receivers 130. It is noted that a combination of different types of receivers/transmitters can be utilized in accordance with this disclosure.

Receivers 130 (and/or transmitters 120) can be arranged in an array, such as a two dimensional array. A two dimensional array can comprise each of receivers 130 locate on or substantially on a same plane. In another aspect, receivers 130 can be arranged linearly, in a triangular fashion, or in other configurations. Furthermore, system 100 can comprise two or more receivers 130 (e.g., three, four, etc.) arranged in a desired configuration. It is noted that receivers 130 can be configured to aim fields of detection in determined directions. Such fields of detection can be set constant and/or alterable (e.g., programmably configurable).

While receivers 130 are described as determining a proximity, distance, speed, direction, etc., for sake of brevity, it is noted that the receivers 130 can be utilized in connection with various components. For example, proximity can be determined by processor 102, a counter (not shown), or other device in communication with receivers 130.

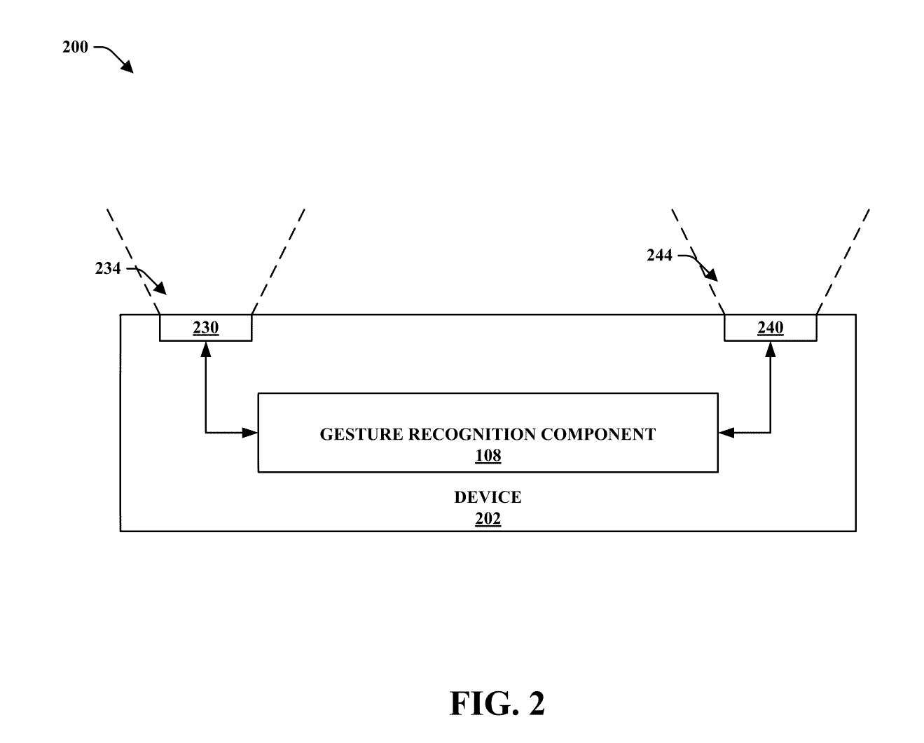

Turning to FIG. 2, with reference to FIG. 1, there depicted are cross sectional views of system 200. While system 200 is depicted with two acoustic sensors (e.g., MEMS microphones), it is noted that system 200 can comprise other acoustic sensors not shown for brevity. As depicted, system 200 can comprise device 202. Device 202 can be any type of device in accordance with embodiments disclosed herein, such as, smart phones, tablet computers, e-readers, monitors, televisions, remote controls, set top boxes, control panels (e.g., automotive control panels, and the like), desktop computers, laptop computers, and the like. Moreover, device 202 can comprise some or all components of system 100, such as gesture recognition component 108. In another aspect, device 202 can comprise acoustic sensors 230 and 240, respectively. While shown as separate components, it is noted that acoustic sensors 230 and 240 can be coupled to or can be comprised within gesture recognition component 108.

System 200 depicts acoustic sensors 230 and 240 in a coplanar configuration. Acoustic sensor 230 is depicted with detection region or a field of detection 232 and acoustic sensor 240 is depicted with field of detection 242. In operation, when an object is in a field of detection 232 and is a threshold distance from acoustic sensor 230, acoustic sensor 230 can detect the object as near. Likewise, when an object is in a field of detection 242 and is a threshold distance from acoustic sensor 240, acoustic sensor 240 can detect the object as near. When an object is not in field of detection 232/242, the acoustic sensor 230/240 can respectively detect the object as far or not near. As described herein, sensors 230/240 can determine a different number of proximities (e.g., near, intermediated, far, etc.) and/or distances.

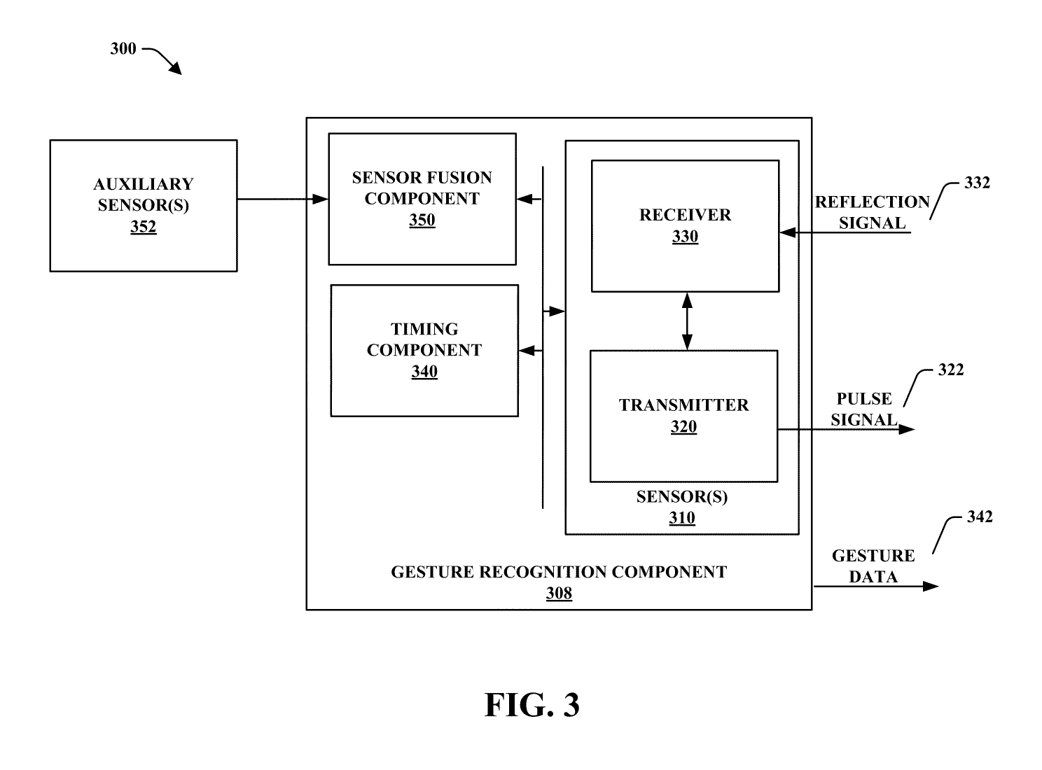

Turning now to FIG. 3, there depicted is a system 300 that is configured for sensor fusion and gesture recognition in accordance with various embodiments described herein. While, system 300 is depicted as comprising a number of components, it is noted that system 300 can comprise various other components (not shown). Furthermore, while components are depicted as separate components, it is further noted that the various components can be comprised in one or more components. It is to be appreciated that system 300 can be used in connection with implementing one or more of the systems or components shown and described in connection with other figures disclosed herein. Moreover, like named components associated with the various figures described herein can perform similar or identical functions and/or comprise similar or identical circuitry, logic, and the like. For example, sensor(s) 310 can perform substantially similar functions as sensor(s) 110 and/or can comprise substantially similar devices and/or circuitry (e.g., MEMS microphone(s) and/or audio sensors).

In another aspect, system 300 can include a memory (not shown) that stores computer executable components and a processor (not shown) that executes computer executable components stored in the memory. Gesture recognition component 308 can comprise a sensor(s) 310 (which can generate and/or received ultrasound signals), a timing component 340 (which can determine time sequences), and sensor fusion component 350 (which can fuse input received from various sensors).

In embodiments, system 300 can include or be coupled to auxiliary sensors 352. Auxiliary sensors 352 can comprise various types and/or numbers of sensors. For instance, auxiliary sensors 352 can comprise IR sensors, pressure sensors, cameras (e.g., video cameras, etc.), acoustic sensors (e.g., microphones, non-MEMS microphones, etc.), motion sensors, inertia sensors, and the like. For example, a device, such as a smart phone, can comprise a number of sensors. The number of sensors can include MEMS microphones (e.g., sensor(s) 310), IR sensors, motion sensors (e.g., gyroscopes, etc.), and/or other sensors. It is noted that sensors of auxiliary sensor(s) 352 can be configured to perform one or more tasks, such as determining a level or change in ambient light, determining direction of an object in motion, determining distance of an object, detecting motion of system 300, tracking an object, determining a position of an object, detecting speech, and the like.

Sensor fusion component 350 can receive input from sensor(s) 310 and/or auxiliary sensor(s) 352. The input from the various sensors (e.g., as raw sensory data and/or data derived from raw sensory data) can be fused or combined, such as via a sensory fusion algorithm or process. Such sensory fusion processes can utilize Kalman filtering, central limit theorem, and/or other functions/algorithms. Furthermore, sensor fusion component 350 can be configured to receive data, for a fusion process, that can originate from different types of sensors. Likewise, sensor fusion component 350 can comprise a number of subcomponents that can be associated with one or more of auxiliary sensor(s) 352 and/or that can utilize direct fusion, indirect fusion, and/or a combination thereof. Direct fusion can comprise fusion of sensor data from a set of heterogeneous or homogeneous sensors, soft sensors, and history values of sensor data. In another aspect, indirect fusion can comprise fusion based, at least in part, other data such as a priori knowledge about an environment and human input.

Sensor fusion component 350 can alter (e.g., improve) gesture recognition of system 300. Altering the gesture recognition can include increasing the accuracy or dependability of gesture recognition, increase a number of identifiable gestures, and the like. For instance, auxiliary sensor(s) 352 can sense ambient light. Information associated with the sensed ambient light can be fused with information from the sensor(s) 310 and/or timing component 340. The resulting fusion of data can be utilized to more accurately detect gestures.

While sensor fusion component 350 is described as fusing sensor input from various sensors, it is noted that information from the various sensors may or may not be fused according to various embodiments. For instance, certain sensors of auxiliary sensors 352 can be configured for detecting a triggering event. The triggering event can initiate a gesture recognition process. In at least one embodiment, auxiliary sensors 352 can comprise a microphone. When the microphone receives input, sensor fusion component 350 (and/or other components, such as a speech recognition component—not shown) can recognize a speech pattern. The speech pattern can be utilized as a trigger for initiating or altering a gesture recognition process. For example, a user can interact with a user device comprising system 300. The user can provide speech such as, “unlock phone,” and system 300 can recognize the phrase. In response to recognizing the phrase, gesture recognition component 308 can initiate a gesture recognition process. If a user provides a proper gesture and/or series of gestures, then the user device will be unlocked. In this manner, system 300 can be configured to avoid false or unintentional pattern recognition (e.g., accidentally unlock a phone), but can maintain a hands-free or touch-free operation.

In some embodiments, functions of a device can be varied based on input from auxiliary sensor(s) 352. For instance, auxiliary sensor(s) 352 can determine a level of ambient light and gesture recognition component 308 can generate instructions for a device based on a detected gesture and the level of ambient light. For example, a user can interact with a user device in a dim or dark room. System 300 can determine that the room is dim or dark based on a detected level of ambient light. A user can then provide a vertical swipe (e.g., up or down swipe) to change a brightness of an interface of the user device. In a different environment, system 300 can determine that the user is in a particularly loud area (e.g., a subway) via the auxiliary sensor(s) 352. In this environment, a vertical swipe can change a volume (e.g., ring tone volume) of the user device.

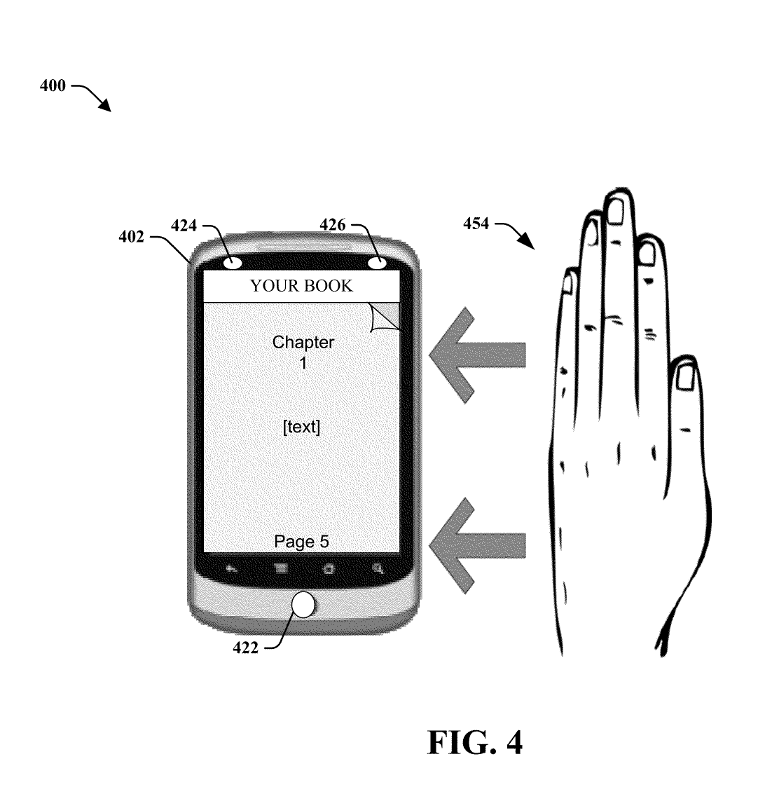

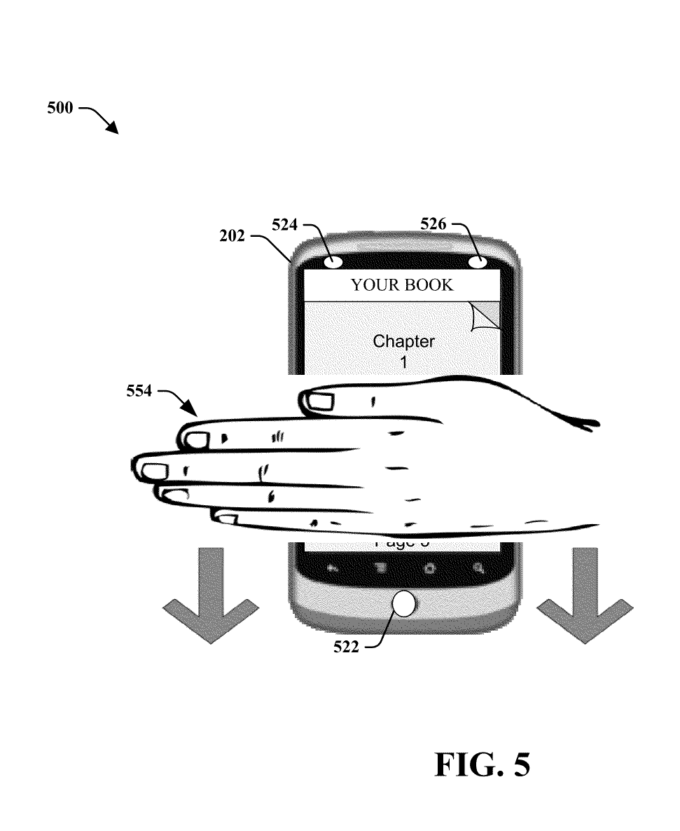

Turning now to FIGS. 4-5, with reference to FIG. 1, there depicted are exemplary systems 400 and 500 respectively. Systems 400/500 can comprise mobile devices 402/502, respectively. It is noted that mobile device 402/502 can comprise all or some components of system 100 and/or various other components not shown for sake of brevity. While depicted as mobile devices, it is appreciated that mobile devices 402/502 can comprise various other devices in accordance with aspects disclosed herein.

System 400 can comprise acoustic receivers 422, 424, and 426 (e.g., MEMS microphones) arranged in an array. Each of acoustic receivers 422, 424, and 426 may comprise different configurations and/or designs. Moreover, each of the acoustic receivers 422, 424, and 426 can utilize various frequency response transfer functions. While acoustic receivers 422, 424, and 426 are depicted in a triangular arrangement, it is noted that acoustic receivers 422, 424, and 426 can be in various other arrangements. Moreover, a different number of acoustic receivers can be utilized. In another aspect, acoustic receivers 422, 424, and 426 can be configured to generate and/or receive acoustic signals. In some embodiments, other components such as a microphone (not shown), speaker (not show), or other component can be included in system 400 to generate acoustic signals.

In an exemplary embodiment, timing component 140 can be configured to determine a time sequence associated with hand 454 passing through various fields of detection of acoustic receivers 422, 424, and 426. For example, a user can use their hand (e.g., hand 454) to perform a horizontal waive (e.g., right to left and/or left to right). If the hand is within a threshold proximity or distance, acoustic receivers 422, 424, and 426 can each detect when the hand is in proximity with the respective acoustic receivers 422, 424, and 426. In another aspect, each acoustic receiver 422, 424, and 426 can detect when the hand is no longer in proximity with the respective acoustic receivers 422, 424, and 426. An entry time can be associated with the hand 454 being detected in proximity and an exit time can be associated with the hand 454 no longer being in proximity. As such, a pair of times (e.g., entry and exit times) or a time period can be associated with detection periods for each of the acoustic receivers 422, 424, and 426. Based on the entry and exit times, timing component 140 can determine a time sequence.

Gesture recognition component 108 can recognize a gesture based on the time sequence. In embodiments, gesture recognition component 108 can utilize a gesture library and/or a gesture recognition process (e.g., gesture recognition algorithms executed by processor 102 and stored in memory 104) to recognize the gesture. For instance, a right to left horizontal gesture can be associated with a first time sequence and a left to right horizontal gesture can be associated with a second time sequence. It is appreciated that other gestures can be recognized, such as diagonal gestures, vertical gestures, two-handed gestures, push/pull gestures, and the like, as described herein. In another aspect, gestures may be associated with less than all of the receivers 130 detecting an object. Further, gestures can be associated with one or more gestures detecting a constant proximity of an object.

In embodiments, a gesture can be determined based on a relationship between the entry and exit times. For instance, the relationship can be a temporal relationship that compares when various entry and exit times associated with the acoustic receivers 422, 424, and 426. In an example, if a user swipes hand 454 from right to left, acoustic receiver 426 will first detect the hand 454, acoustic receiver 422 will then detect the hand 454, and finally acoustic receiver 424 will detect the hand. Likewise, acoustic receiver 426 will first detect the hand 454 exiting from a respective field of detection, followed by acoustic receiver 422 detecting the hand 454 exiting from a respective field of detection, and final acoustic receiver 424 will detect the hand 454 exiting from a respective field of detection. A left to right hand swipe, would comprise acoustic receiver 424 first detecting the hand 454, followed by acoustic receiver 422 detecting the hand 454, and finally acoustic receiver 426 detecting the hand 454. In a similar manner, acoustic receiver 424 first detecting the hand 454 exiting a respective field of detection, followed by acoustic receiver 422 detecting the hand 454 exiting a respective field of detection, and finally acoustic receiver 426 detecting the hand 454 exiting a respective field of detection. It is noted that detection periods of the acoustic receivers 422, 424, and/or 426 can overlap, partially overlap, and/or be disparate (non-overlapping). It is noted that the above time sequences are described for exemplary purposes. As such, a user may make a gesture that may stop over a particular sensor for a period of time. For example, a user swiping hand 454 from right to left may end their gesture with hand 454 over acoustic receiver 424. Various embodiments can account for such imperfect gestures and can still recognize the gesture.

System 500 depicts a hand 554 making a vertical gesture (or vertical wave). The vertical wave and be in a down direction (as depicted) or in an up direction. In embodiments, system 500 can comprise acoustic receivers 522, 524, and 526. System 500 can be configured to perform all or some functions of other embodiments (e.g., system 100, 200, 300, 400, etc.) described herein.

During operation, a user can make a gesture with hand 554. As depicted, the user can make a vertical gesture in a down direction (e.g., downward swipe). In a downward swipe, acoustic receiver 526 and/or 524 will first detect the hand 554. It is noted that acoustic receiver 526 and 524 may detect the hand 554 at the same time or substantially the same time. Acoustic receiver 522 will then detect the hand 554 at a time after detection of hand 554 by acoustic receiver 526 and/or 524. Likewise, acoustic receiver 524 and 526 will first (e.g., concurrently or substantially concurrently) detect the hand 554 exiting from respective fields of detection, followed by acoustic receiver 522 detecting the hand 554 exiting from a respective field of detection. An up hand swipe would similarly correspond to the down hand swipe, except for reversing the order of entry and exits.

A recognized gesture can be associated with an operation or function of mobile device 402/502. The operation and/or function can be device specific, based on an open screen/application, user defined, or the like. For example, while reading an electronic book and/or periodical, a user making a right to left (e.g., right to left) gesture can flip a page of the electronic book and/or periodical to advance to the next page. A right gesture (left to right) gesture can advance to a previous page. In another aspect, a user can navigate between screens, pictures, contacts, web pages, tabs, scroll or navigate a webpage, or the like. As another example, a down hand swipe (up to down) and/or up hand swipe may close an open mobile application (e.g., “app”), and/or pause the application. According to at least one embodiment, an up/down hand swipe can control a brightness of a display, a volume, and/or other aspects of a device. Moreover, the gestures and/or a pattern of gestures can be utilized to unlock a device, start an application, close an application, etc. Furthermore, a user can provide user defined rules for gestures. For instance, a user can define that a speed of a gesture should control a number of pages flipped, a speed of navigation (e.g., scrolling), or the like. In another aspect, a “stop” gesture made by placing a hand in a fixed position can stop scrolling during navigation.

In another aspect, system 100 can detect a push or pull gesture where an object is moving towards or away from a device (e.g., device 402/502), respectively. For example, receivers 130 can be configured to determine (e.g., via a counter, processor 102, and/or the like) distances and/or determine (e.g., via a counter, processor 102, and/or the like) changes in proximity based on parameters associated with received signals. As signals are received by receivers 130 pulses (e.g., pulses in signals, time pulses, etc.) can be analyzed. For instance, if an object is moving towards/away from device 402/502, then times between received pulses, amplitudes of received pulses, or other parameters may be altered. As an example, if times between received pulses increase/decrease, then receivers 130 can determine whether an object is increasing/decreasing in proximity. While time of flight is described, it is noted that various other techniques can be utilized to determine an object changing in a proximity.

In an aspect, receivers 130 can determine push/pull gestures based on the determined changes in proximity. For example, a user can move hand 454/545 in a direction towards or away from device 402/502. As the object moves towards/away, timing component 140 can determine a time sequence associated with the changes in proximity and gesture recognition component 108 can recognize a gesture based on the time sequences associated with the changes in proximity.

While various embodiments describe an object in motion (e.g., wave of a hand), it is noted that the motion can be relative to a device. As such, the device, the object, and/or both may be in motion. Furthermore, while embodiments describe a single object in motion, it is noted that a different number of objects may be in motion and/or detected. For example, a user can utilize two hands to make a gesture. Embodiments can determine time sequences based on the two hands and a two handed motion can be recognized. In another aspect, gesture recognition component 108 can recognize sequences of gestures, which may be and/or may be comprised by other gestures (e.g., right to left followed by left to right swipe).

In embodiments, gesture recognition component 108 can generate output (gesture data 142). Gesture data 142 can be utilized according to desired applications (e.g., hand held electronic applications, automotive applications, medical applications, wearable electronics applications, etc.). In embodiments, gesture data 142 can comprise instructions that instruct a device (e.g., device 402/502) to perform operations.

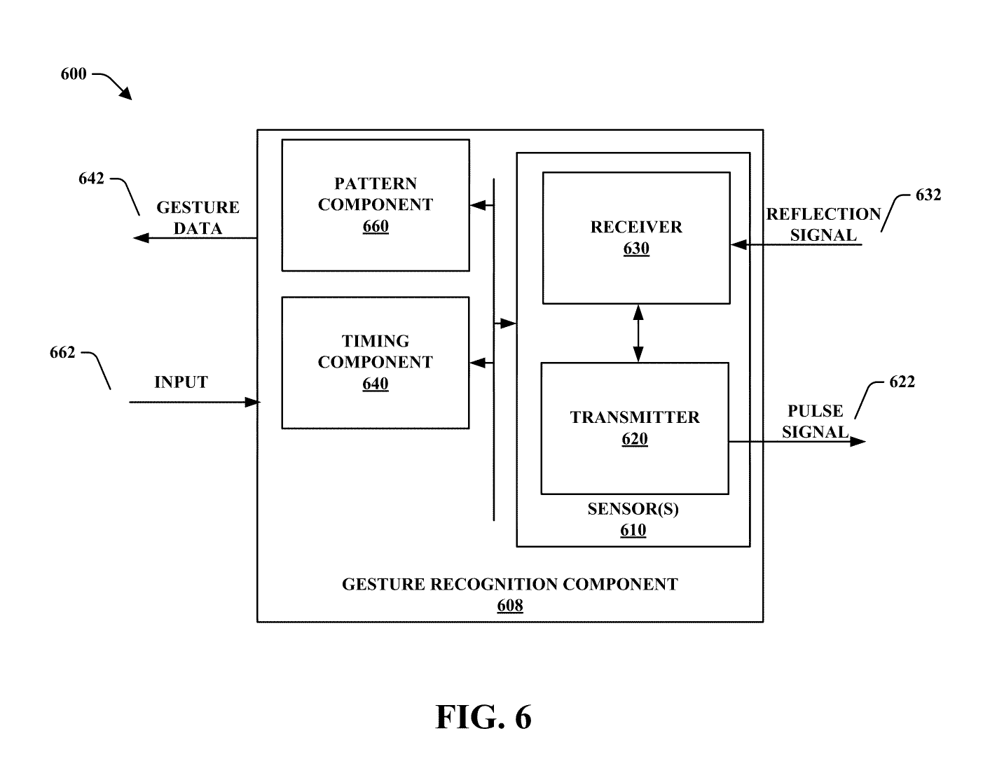

Turning now to FIG. 6, there depicted is a system 600 that can detect gestures and recognize patterns in accordance with various embodiments described herein. While, system 600 is depicted as comprising a number of components, it is noted that system 600 can comprise various other components (not shown). Furthermore, while components are depicted as separate components, it is further noted that the various components can be comprised in one or more components. It is to be appreciated that system 600 can be used in connection with implementing one or more of the systems or components shown and described in connection with other figures disclosed herein. Moreover, like named components associated with the various figures described herein can perform similar or identical functions and/or comprise similar or identical circuitry, logic, and the like. For example, sensor(s) 610 can perform substantially similar functions as sensor(s) 110 and/or can comprise substantially similar devices and/or circuitry (e.g., MEMS microphone(s) and/or audio sensors).

In another aspect, system 600 can include a memory (not shown) that stores computer executable components and a processor (not shown) that executes computer executable components stored in the memory. Gesture recognition component 308 can comprise a sensor(s) 610 (which can generate and/or received ultrasound signals), a timing component 640 (which can determine time sequences), and a pattern component 660 (which can recognize and/or store patterns).

Pattern component 660 can comprise a pattern library stored in a memory. The pattern library can comprise a number of identified patterns. Patterns can be identified based on a time sequence or the like. For example, pattern component 660 can receive a time sequence (e.g., via timing component 640). Pattern component 660 can analyze and/or compare the time sequence to stored time sequences to identify a pattern in the pattern library, such as via a search algorithm or process. For instance, times between a first, second, and third set of exit and entry times can form a time sequence, pattern component 660 can identify a gesture as a left to right swipe, a right to left swipe, an up swipe, a down swipe, a push swipe, a pull swipe, a horizontal swipe, etc.

In another aspect, a user can provide input to customize or identify a user defined gesture. The user defined gesture can be stored by pattern component 660 in a pattern library. In another aspect, the user defined gesture can be a combination or sequence of gestures. Furthermore, the user can provide input to define rules associated with gestures. For instance, a user can define a sequence of gestures to unlock a device. In another aspect, a user can disable a gesture, such as during a video chat or the like.

In various embodiments, gesture recognition component 608 can recognize gestures in response to a triggering event and/or in an “always on” mode. A triggering event can comprise a device in an active mode, in a sleep mode, operating a particular function or application (e.g., an internet browser, an electronic media reader, etc.), based on user input (e.g., voice command, pressing a button, etc), or other triggering event. Always on refers to system 600 continually iterating transmitting, receiving, and/or recognizing gestures. In embodiments, modes and triggering events can be toggled on/off based on user input and/or defined rules.

In another aspect, pattern component 660 can calibrate or alter a detection/identification process to refine or alter gesture recognition. In order to provide for or aid in the numerous inferences described herein, system 600 can examine the entirety or a subset of the data to which it is granted access and can provide for reasoning about or infer states of the system, environment, etc. from a set of observations as captured via events and/or data. The inferences can provide for calibrating frequencies, calibrating thresholds, or can generate a probability distribution over states, for example. The inference can be probabilistic—that is, the computation of a probability distribution over states of interest based on a consideration of data and events. An inference can also refer to techniques employed for composing higher-level events from a set of events and/or data.

Such an inference can result in the construction of new events or actions from a set of observed events and/or stored event data, whether or not the events are correlated in close temporal proximity, and whether the events and data come from one or several event and data sources. Various classifications (explicitly and/or implicitly trained) schemes and/or systems (e.g., support vector machines, neural networks, expert systems, Bayesian belief networks, fuzzy logic, data fusion engines, etc.) can be employed in connection with performing automatic and/or inferred actions in connection with the claimed subject matter.

A classifier can map an input attribute vector, x=(x1, x2, x3, x4, xn), to a confidence that the input belongs to a class, such as by f(x)=confidence(class). Such classification can employ a probabilistic and/or statistical-based analysis (e.g., factoring into the analysis utilities and costs) to infer an action that a user desires to be automatically performed. A support vector machine (SVM) is an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, and probabilistic classification models providing different patterns of independence can be employed. Classification as used herein also is inclusive of statistical regression that is utilized to develop models of priority.

While several example embodiments are provided, it is noted that aspects of this disclosure are not limited to the exemplary embodiments. As such, the various embodiments disclosed herein can be applied to numerous applications. In exemplary embodiments, systems and methods described herein can be applied to smart phones, hand held gaming devices, hand held electronics, notebook computers, desktop computers, and the like. Such systems can be utilized to gestures to control various functions, such as standby-mode activation/de-activation, interface (e.g., keypad backlight, view screen, etc.) activation/deactivation, speakerphone activation/deactivation, volume adjustments, or the like. In at least one other embodiment, various systems disclosed can be included within a digital camera, smart camera, or the like. It is further noted, that gesture recognition systems disclosed herein can be utilized as “buttons” or non-pressured buttons, such as for autofocus of a camera system (e.g., wherein proximity can be near zero). In another example, embodiments disclosed herein can be incorporated in wearable electronics, such as headphones (e.g., turn on/off based on proximity). For instance, a headset of headphones can recognise gestures to control playback of media, volumes, and the like.

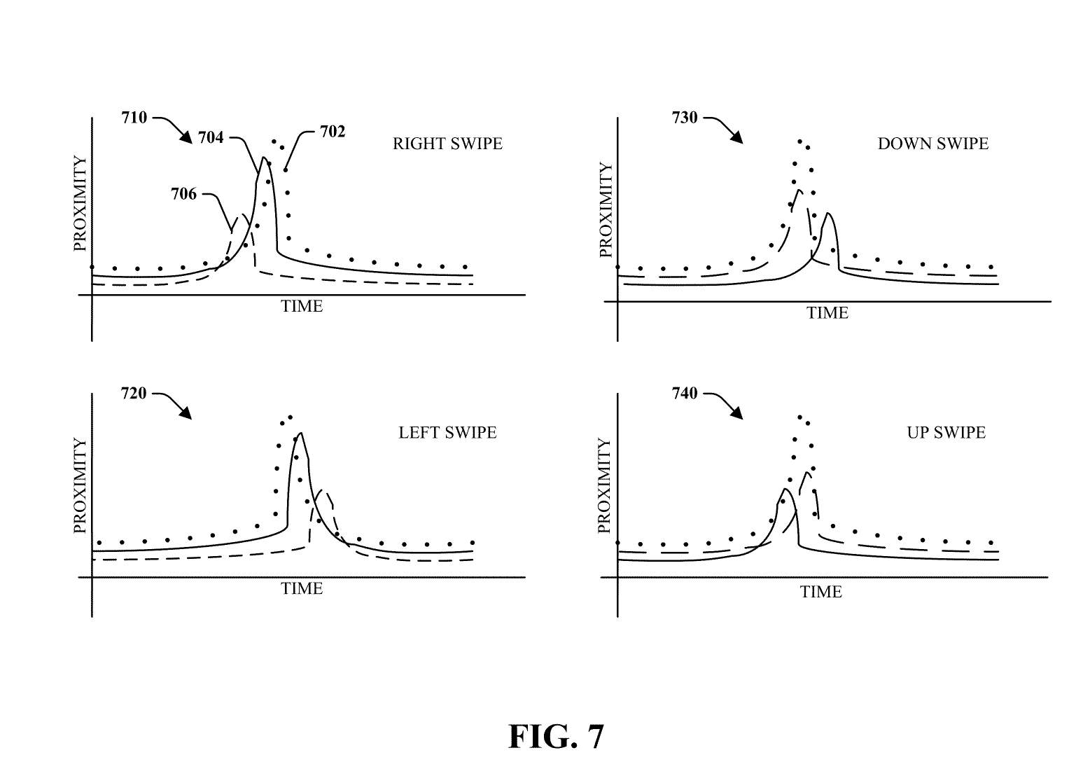

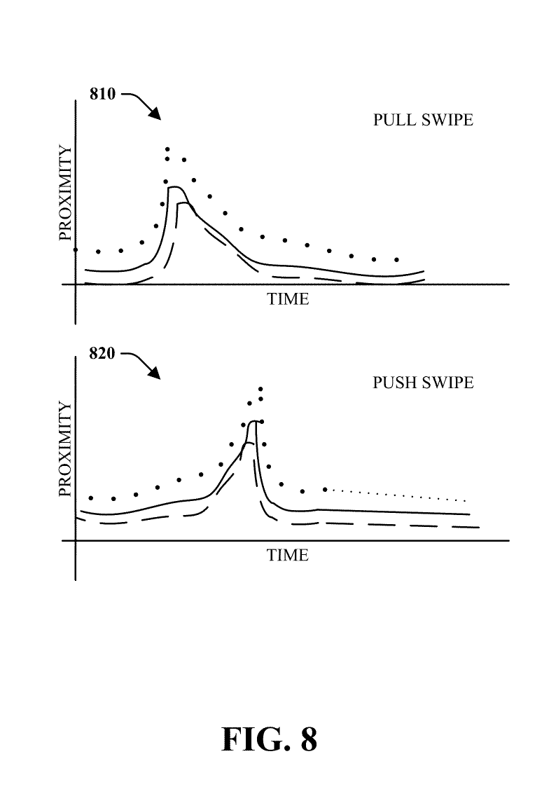

Turning to FIGS. 7-8, there depicted are exemplary graphs 710, 720, 730, 740, 810, and 820. The exemplary graphs depict a proximity detection of three acoustic sensors versus passage of time. Graph 710 is associated with a left to right swipe, graph 720 is associated with a right to left swipe, graph 730 is associated with a down swipe, graph 740 is associated with an up swipe, graph 810 is associated with a pull swipe, and graph 820 is associated with a push swipe. In the exemplary graphs, dotted lines (e.g., line 702) represent data of a first acoustic sensor, solid lines (e.g., line 704) represents data of a second acoustic sensor, and dashed line (e.g., line 706) represent data of a third acoustic sensor. It is noted that the dotted lines, solid lines, and dashed lines, of each of the various graphs are respectively associated with first, second, and third acoustic sensors.

As depicted, graph 710 describes a right swipe (e.g., left to right swipe) where a hand or other object is first detected in proximity to the third acoustic sensor (e.g., acoustic receivers 424/524). The object is next detected by the second acoustic sensor (e.g., acoustic receivers 422/522) and is final detected by the first acoustic sensor (e.g., acoustic receivers 426/526).

Graph 720 describes a left swipe (e.g., right to left swipe) where a hand or other object is first detected in proximity to the first acoustic sensor (e.g., acoustic receivers 426/526). The object is next detected by the second acoustic sensor (e.g., acoustic receivers 422/522) and is final detected by the third acoustic sensor (e.g., acoustic receivers 424/524).

Graph 730 depicts a down swipe, where the object is first detected in proximity to the first acoustic sensor (e.g., acoustic receivers 426/526) and the third acoustic sensor (e.g., acoustic receivers 424/524). It is noted that the first and third acoustic sensors can detect the object at the same time or substantially the same time. There may be some lapse in time due to the object not being fully detected or fully in view of one of the receivers and/or due to processing delays. The object is next detected by the second acoustic sensor (e.g., acoustic receivers 422/522).

Graph 740 depicts an up swipe, where the object is first detected in proximity to the second acoustic sensor (e.g., acoustic receivers 422/522). The object is next detected by the first acoustic sensor (e.g., acoustic receivers 426/526) and the third acoustic sensor (e.g., acoustic receivers 424/524). It is noted that the first and third acoustic sensors can detect the object at the same time or substantially the same time.

Graphs 810 and 820 depict a pull swipe and a push swipe, respectively. In a push/pull swipe, the object is detected in proximity by each of the acoustic sensors at the same time or substantially the same time. However, the object moves or changes in proximity to each of the acoustic sensors during the same period or substantially the same period. For instance, in graph 810, each of the first, second, and third acoustic sensors detects the object at or about the same time. On the left side or upward curve, the graph depicts a sharp increase (e.g., large slope) with respect to the right side or downward curve, which depicts a gradual or smaller relative slope. In an aspect, the gradual decline is due to the object being moved away from the device.

Graph 810 depicts each of the first, second, and third acoustic sensors detecting the object at or about the same time. On the left side or upward curve, the graph depicts a gradual or smaller relative slope when compared to the right side (or downward curve). In an aspect, the gradual incline is due to the object being moved away from the device. In some embodiments, the right side or downward curve may exhibit a sustained period of not changing proximity associated with a user not moving their hand once it is “pushed” or moved towards a device. It is noted that some embodiments may not be sensitive to a user's movements as the user may move too fast in either direction, may move erratically, and/or may cause errors when initiating a push/pull gesture. For example, when a user positions her/his hand over a device to make a push/pull gesture, the device may detect a gesture based on the user position her/his hand. In such embodiments, a user can trigger the gesture detection based on leaving their hand in a fixed position or substantially fixed position for a period of time, and/or based on other triggering events. For example, to initiate a pull gesture, the user can first position their hand at a close proximity. The user can leave their hand at the proximity for a determined amount of time (e.g., half a second). The user can then move their hand away from the device and the device can detect a pull gesture. A push gesture can be detected in a similar manner where a user leaves a hand in a far or intermediary distance for a determined amount of time and then moves their hand towards the device.

It is further noted that a user can provide input to alter sensitivity of such gestures and/or configure a trigger. In another aspect, a device can learn a user's habits and/or gestures based on a history associated with the user interacting with the device. The history can be stored, for example, in a memory internal and/or external (e.g., in a server, in the cloud, etc.) to the device. In an aspect, an externally stored history can be communicated to other devices associated with the user to calibrate gesture recognition across devices (e.g., a user's smart phone, tablet computer, e-reader, etc.).

Various other embodiments can utilize systems and methods described herein in applications, such as, but not limited to, home appliances, printing devices, industrial systems, automotive systems, navigation systems, global positioning satellite (GPS) systems, and the like. In an aspect, home appliances can include irons (which can turn on/off based on proximity detection), power tools, personal electronics, refrigerators (e.g., selecting ice or water from a dispenser, etc.), coffee machines (or other beverage machines which can select a liquid, size, temperature, etc.), robotic vacuum machines (which can navigate around objects based on proximity detection), and the like. In another aspect, industrial and automotive applications can include applications that utilize gesture controlled switches, automated faucets (e.g., turn on/off, change temperature), automated hand drying machines, mechanical switches, disc detection systems (e.g., in energy meters), and the like. While various examples have been described, it is noted that aspects of the subject disclosure described herein can be applied to many other applications.

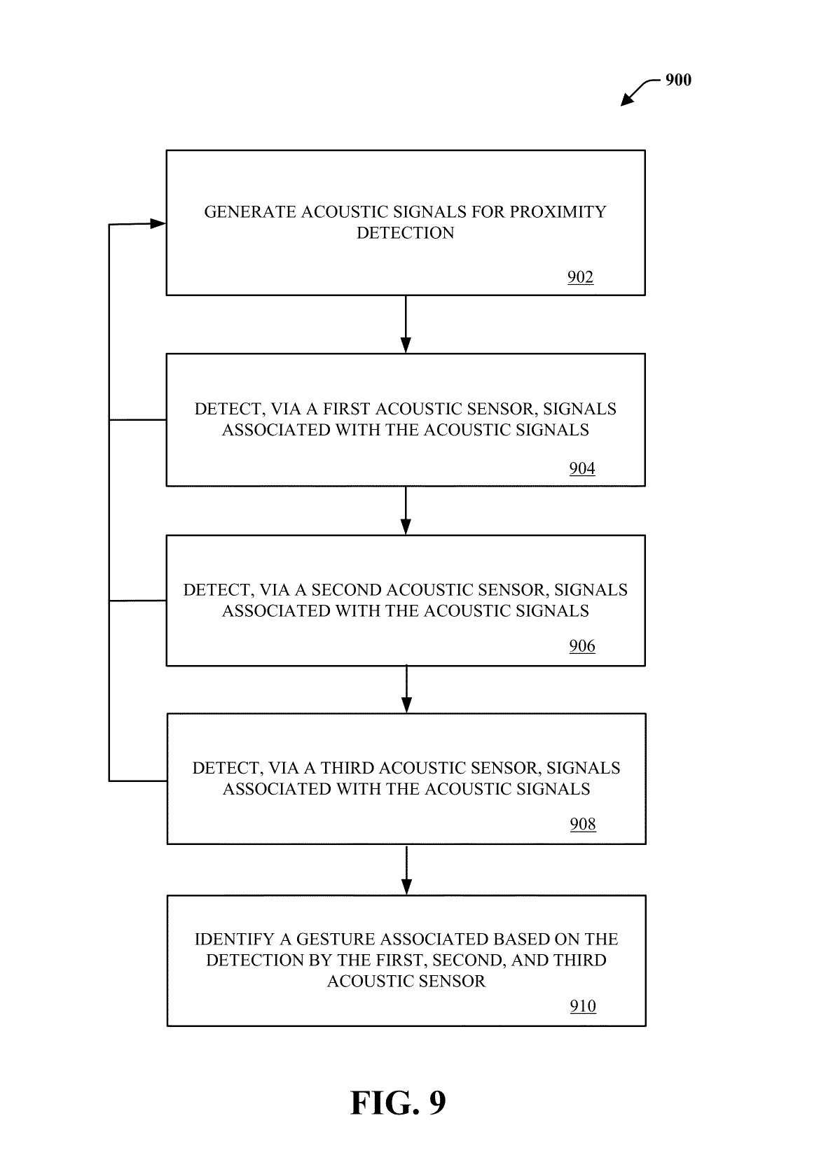

In view of the subject matter described supra, methods that can be implemented in accordance with the subject disclosure will be better appreciated with reference to the flowcharts of FIGS. 9-11. While for purposes of simplicity of explanation, the methods are shown and described as a series of blocks, it is to be understood and appreciated that such illustrations or corresponding descriptions are not limited by the order of the blocks, as some blocks may occur in different orders and/or concurrently with other blocks from what is depicted and described herein. Any non-sequential, or branched, flow illustrated via a flowchart should be understood to indicate that various other branches, flow paths, and orders of the blocks, can be implemented which achieve the same or a similar result. Moreover, not all illustrated blocks may be required to implement the methods described hereinafter.

### Exemplary Methods

FIG. 9 depicts an exemplary flowchart of non-limiting method 900 associated with a MEMS acoustic sensor-based gesture recognition system, according to various non-limiting aspects of the subject disclosure. As a non-limiting example, exemplary methods 900 can comprise determining a proximity associated with an object and acoustic sensors of an array of MEMS acoustic sensor in a system (e.g., system 100, 200, etc.). A gesture can be determined or recognized based on times associated with the proximity detection by the array of MEMS acoustic sensors.

At 902, a system (e.g., system 100, 200, etc.) can generate (e.g., a sensor comprising transmitter 120) acoustic signals for proximity detection. In an aspect, one or more MEMS acoustic sensors and/or other components of the system (e.g., speaker) can generate the acoustic signals. As described herein, the plurality of acoustic signals can comprise a set of pulse in a determined frequency (e.g., ultrasound signals). It is noted that each pulse can be of a common or distinct frequency.

At 904, the system can detect, via a first acoustic sensor (e.g., a sensor comprising a first receiver 130), signals associated with the acoustic signals. Detecting the signals can include determining entry and exit times associated with an object being detected in a determined proximity. In another aspect, detecting the signals can include determining speed, direction, or the like of the object.

At 906, the system can detect, via a second acoustic sensor (e.g., a sensor comprising a second receiver 130), signals associated with the acoustic signals. At 908, the system can detect, via a third acoustic sensor (e.g., a sensor comprising a third receiver 130), signals associated with the acoustic signals. It is noted that detection of signals by the various acoustic sensors can occur simultaneously, substantially simultaneously, and/or at overlapping or non-overlapping times. It is noted that the generating and detection by various components can be iterated in an always on fashion and/or based on detection of a triggering event to facilitate identification of one or more gestures.

While three acoustic sensors or described, it is noted that the method can utilize a different number of acoustic sensors. Furthermore, an object may or may not be detected by each of the acoustic sensors and a gesture can be identified based on detection by less than all of the acoustic sensors.

At 910, the system can identify (e.g., via gesture recognition component 108) a gesture associated based on the detection by the first, second, and third acoustic sensor. As described herein, identifying the gesture can be based on a time sequence associated with detection by the first, second, and/or third acoustic sensors.

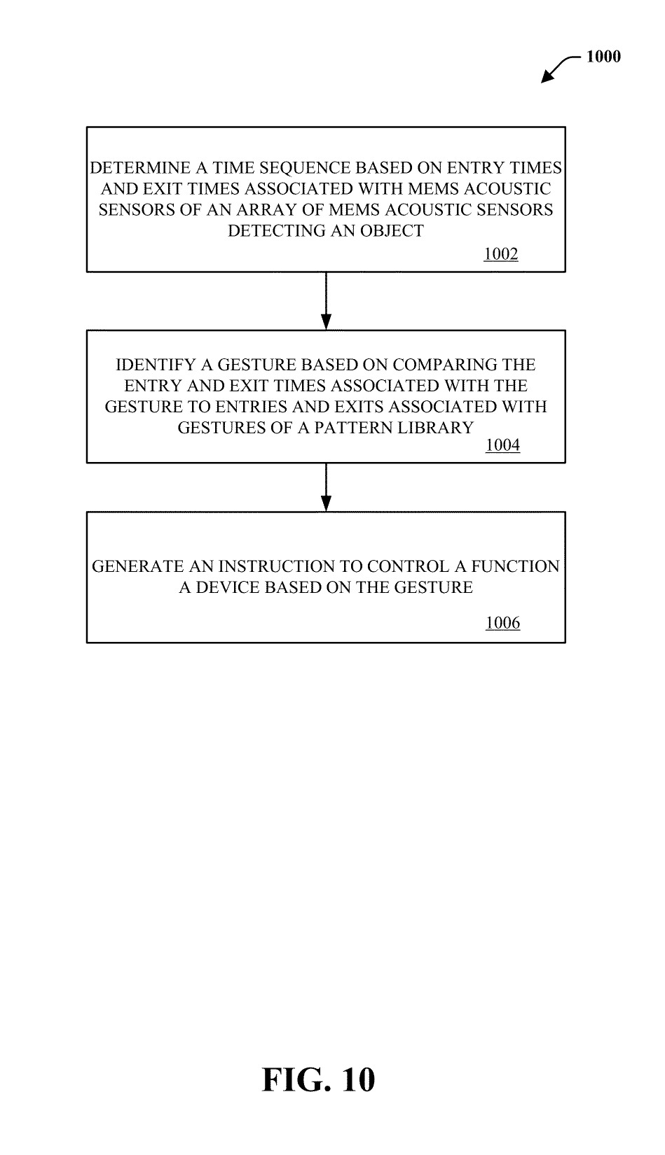

FIG. 10 depicts an exemplary flowchart of non-limiting method 1000 associated with a MEMS acoustic sensor-based gesture recognition system and control of a device, according to various non-limiting aspects of the subject disclosure. As a non-limiting example, exemplary methods 1000 can comprise identifying a gesture and generating an instruction to control a function of a device based on the gesture.

At 1002, a system (e.g., system 100, 200, etc.) determines (e.g., via timing component 140/640) a time sequence based on entry times and exit times associated with MEMS acoustic sensors of an array of MEMS acoustic sensors detecting an object. A set of entry and exit times can correspond to an object being in a field of detection associated with a MEMS acoustic sensor. It is noted that each acoustic sensor of the array of MEMS acoustic sensors can be associated with a different set of entry and exit times.

At 1004, the system can identify (e.g., via gesture recognition component 108/608) a gesture based on comparing the entry and exit times associated with the gesture to entries and exits associated with gestures of a pattern library. For example, the entry and exit times can be associated with a time sequence that can be compared to other time sequences stored in a memory. It is noted that other techniques can employ algorithms to determine a gesture in accordance with various aspects disclosed herein.

At 1006, the system can generate (e.g., via gesture recognition component 108/608) an instruction to control a function of a device based on the gesture. The instruction can be utilized (e.g., via a processor) to control any number of operations and/or functions. Such operations and functions can include navigating a display screen, flipping a page, unlocking a device, turning on/off a device and/or display, controlling an interface device (e.g., display, speaker, etc.), or the like.

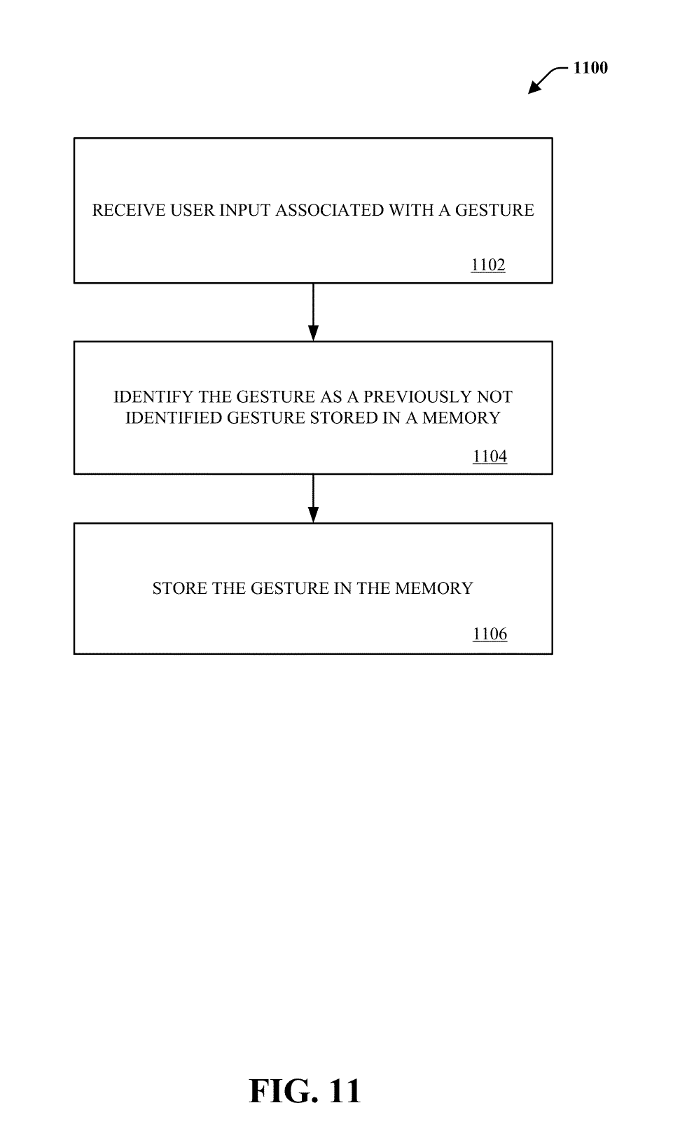

FIG. 11 depicts an exemplary flowchart of non-limiting method 1100 associated with a MEMS acoustic sensor-based gesture recognition system including defining a user defined pattern, according to various non-limiting aspects of the subject disclosure. As a non-limiting example, exemplary methods 1100 can comprise identifying a user defined gesture and storing the gesture in memory.

At 1102, a system (e.g., system 100, 200, etc.) can receive (e.g., via pattern component 660) user input associated with a gesture. The user input can include input (e.g., received via an interface) that indicates the user desires to add a gesture and/or define a user rule for the gesture.

At 1104, the system can identify (e.g., via pattern component 660) the gesture as a previously not identified gesture stored in a memory. For instance, the system can compare the gesture to gestures in a gesture library. In another aspect, the system can identify the gesture based on data from various sensors and/or types of sensors, such as acoustic sensors (e.g., MEMS microphones), light sensors, motion sensors, and the like. In some embodiments, the data from the various sensors can be fused to alter (e.g., enhance) gesture recognition or identification. If the gesture is not in the library, the gesture can be added at 1106. For example, at 1106 the system can store (e.g., via pattern component 660) the gesture in the memory (e.g., memory 104).

The systems and processes described below can be embodied within hardware, such as a single integrated circuit (IC) chip, multiple ICs, an ASIC, or the like. Further, the order in which some or all of the process blocks appear in each process should not be deemed limiting. Rather, it should be understood that some of the process blocks can be executed in a variety of orders, not all of which may be explicitly illustrated herein.

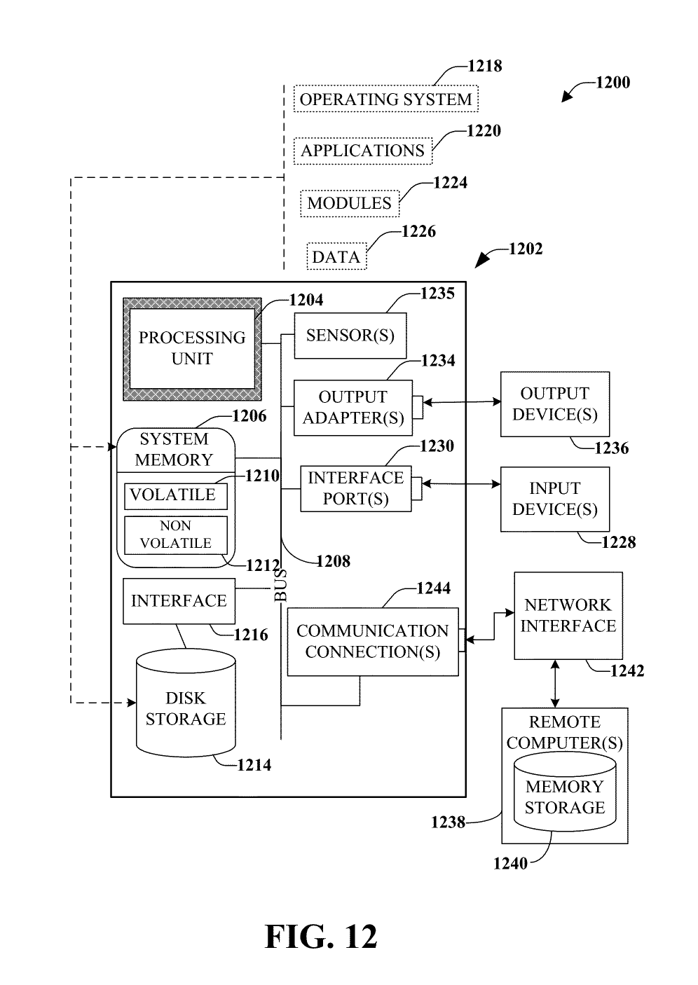

With reference to FIG. 12, a suitable environment 1200 for implementing various aspects of the claimed subject matter includes a computer 1202. The computer 1202 includes a processing unit 1204, a system memory 1206, sensor(s) 1235 (e.g., acoustic sensor(s), pressure sensor(s), temperature sensor(s), etc.), and a system bus 1208. The system bus 1208 couples system components including, but not limited to, the system memory 1206 to the processing unit 1204. The processing unit 1204 can be any of various available processors. Dual microprocessors and other multiprocessor architectures also can be employed as the processing unit 1204.

The system bus 1208 can be any of several types of bus structure(s) including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Personal Computer Memory Card International Association bus (PCMCIA), Firewire (IEEE 1394), and Small Computer Systems Interface (SCSI).

The system memory 1206 includes volatile memory 1210 and non-volatile memory 1212. The basic input/output system (BIOS), containing the basic routines to transfer information between elements within the computer 1202, such as during start-up, is stored in non-volatile memory 1212. In addition, according to present innovations, sensor(s) 1235 may include at least one audio sensor (e.g., MEMS microphone, etc.). Wherein the at least one audio sensor(s) may consist of hardware, software, or a combination of hardware and software. Although, sensor(S) 1235 is depicted as a separate component, sensor(s) 1235 may be at least partially contained within non-volatile memory 1212. By way of illustration, and not limitation, non-volatile memory 1212 can include read only memory (ROM), programmable ROM (PROM), electrically programmable ROM (EPROM), electrically erasable programmable ROM (EEPROM), or flash memory. Volatile memory 1210 includes random access memory (RAM), which acts as external cache memory. According to present aspects, the volatile memory may store the write operation retry logic (not shown in FIG. 12) and the like. By way of illustration and not limitation, RAM is available in many forms such as static RAM (SRAM), dynamic RAM (DRAM), synchronous DRAM (SDRAM), double data rate SDRAM (DDR SDRAM), and enhanced SDRAM (ESDRAM).

Computer 1202 may also include removable/non-removable, volatile/non-volatile computer storage medium. FIG. 12 illustrates, for example, disk storage 1214. Disk storage 1214 includes, but is not limited to, devices like a magnetic disk drive, solid state disk (SSD) floppy disk drive, tape drive, Jaz drive, Zip drive, LS-100 drive, flash memory card, or memory stick. In addition, disk storage 1214 can include storage medium separately or in combination with other storage medium including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM). To facilitate connection of the disk storage devices 1214 to the system bus 1208, a removable or non-removable interface is typically used, such as interface 1216. It is appreciated that storage devices 1214 can store information related to a user. Such information might be stored at or provided to a server or to an application running on a user device. In one embodiment, the user can be notified (e.g., by way of output device(s) 1236) of the types of information that are stored to disk storage 1214 and/or transmitted to the server or application. The user can be provided the opportunity to control having such information collected and/or shared with the server or application (e.g., by way of input from input device(s) 1228).

It is to be appreciated that FIG. 12 describes software that acts as an intermediary between users and the basic computer resources described in the suitable operating environment 1200. Such software includes an operating system 1218. Operating system 1218, which can be stored on disk storage 1214, acts to control and allocate resources of the computer system 1202. Applications 1220 take advantage of the management of resources by operating system 1218 through program modules 1224, and program data 1226, such as the boot/shutdown transaction table and the like, stored either in system memory 1206 or on disk storage 1214. It is to be appreciated that the claimed subject matter can be implemented with various operating systems or combinations of operating systems.

A user enters commands or information into the computer 1202 through input device(s) 1228. Input devices 1228 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 1204 through the system bus 1208 via interface port(s) 1230. Interface port(s) 1230 include, for example, a serial port, a parallel port, a game port, and a universal serial bus (USB). Output device(s) 1236 use some of the same type of ports as input device(s) 1228. Thus, for example, a USB port may be used to provide input to computer 1202 and to output information from computer 1202 to an output device 1236. Output adapter 1234 is provided to illustrate that there are some output devices 1236 like monitors, speakers, and printers, among other output devices 1236, which require special adapters. The output adapters 1234 include, by way of illustration and not limitation, video and sound cards that provide a means of connection between the output device 1236 and the system bus 1208. It should be noted that other devices and/or systems of devices provide both input and output capabilities such as remote computer(s) 1238.

Computer 1202 can operate in a networked environment using logical connections to one or more remote computers, such as remote computer(s) 1238. The remote computer(s) 1238 can be a personal computer, a server, a router, a network PC, a workstation, a microprocessor based appliance, a peer device, a smart phone, a tablet, or other network node, and typically includes many of the elements described relative to computer 1202. For purposes of brevity, only a memory storage device 1240 is illustrated with remote computer(s) 1238. Remote computer(s) 1238 is logically connected to computer 1202 through a network interface 1242 and then connected via communication connection(s) 1244. Network interface 1242 encompasses wire and/or wireless communication networks such as local-area networks (LAN) and wide-area networks (WAN) and cellular networks. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL).

Communication connection(s) 1244 refers to the hardware/software employed to connect the network interface 1242 to the bus 1208. While communication connection 1244 is shown for illustrative clarity inside computer 1202, it can also be external to computer 1202. The hardware/software necessary for connection to the network interface 1242 includes, for exemplary purposes only, internal and external technologies such as, modems including regular telephone grade modems, cable modems and DSL modems, ISDN adapters, and wired and wireless Ethernet cards, hubs, and routers.

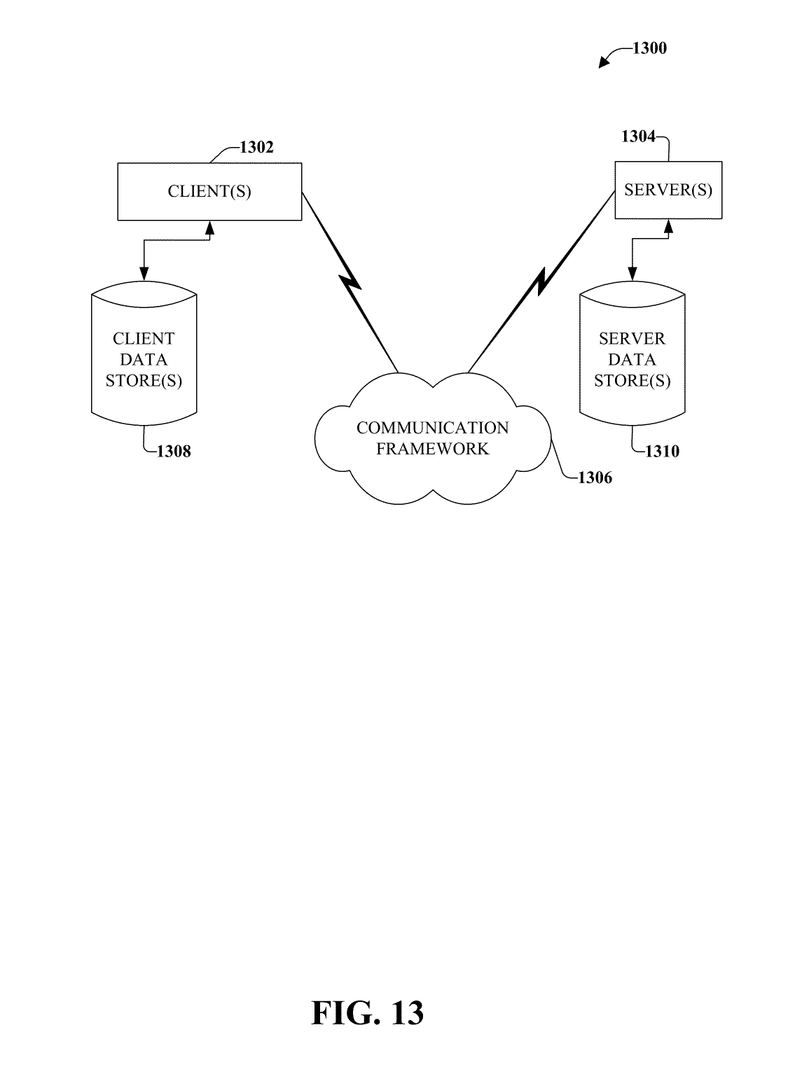

Referring now to FIG. 13, there is illustrated a schematic block diagram of a computing environment 1300 in accordance with this specification. The system 1300 includes one or more client(s) 1302 that may comprise a proximity sensing system according to various embodiments disclosed herein (e.g., laptops, smart phones, PDAs, media players, computers, portable electronic devices, tablets, and the like). The client(s) 1302 can be hardware and/or software (e.g., threads, processes, computing devices). The system 1300 also includes one or more server(s) 1304. The server(s) 1304 can also be hardware or hardware in combination with software (e.g., threads, processes, computing devices). The servers 1304 can house threads to perform transformations by employing aspects of this disclosure, for example. One possible communication between a client 1302 and a server 1304 can be in the form of a data packet transmitted between two or more computer processes wherein the data packet may include sensor data, proximity data, user defined rules, and the like. The data packet can include a cookie and/or associated contextual information, for example. The system 1300 includes a communication framework 1306 (e.g., a global communication network such as the Internet, or mobile network(s)) that can be employed to facilitate communications between the client(s) 1302 and the server(s) 1304.

Communications can be facilitated via a wired (including optical fiber) and/or wireless technology. The client(s) 1302 are operatively connected to one or more client data store(s) 1308 that can be employed to store information local to the client(s) 1302 (e.g., cookie(s) and/or associated contextual information). Similarly, the server(s) 1304 are operatively connected to one or more server data store(s) 1310 that can be employed to store information local to the servers 1304.

In one embodiment, a client 1302 can transfer an encoded file, in accordance with the disclosed subject matter, to server 1304. Server 1304 can store the file, decode the file, or transmit the file to another client 1302. It is to be appreciated, that a client 1302 can also transfer uncompressed file to a server 1304 and server 1304 can compress the file in accordance with the disclosed subject matter. Likewise, server 1304 can encode information and transmit the information via communication framework 1306 to one or more clients 1302.

The illustrated aspects of the disclosure may also be practiced in distributed computing environments where certain tasks are performed by remote processing devices that are linked through a communications network. In a distributed computing environment, program modules can be located in both local and remote memory storage devices.

Moreover, it is to be appreciated that various components described herein can include electrical circuit(s) that can include components and circuitry elements of suitable value in order to implement the embodiments of the subject innovation(s). Furthermore, it can be appreciated that many of the various components can be implemented on one or more integrated circuit (IC) chips. For example, in one embodiment, a set of components can be implemented in a single IC chip. In other embodiments, one or more of respective components are fabricated or implemented on separate IC chips.

What has been described above includes examples of the embodiments of the present disclosure. It is, of course, not possible to describe every conceivable combination of components or methodologies for purposes of describing the claimed subject matter, but it is to be appreciated that many further combinations and permutations of the subject innovation are possible. Accordingly, the claimed subject matter is intended to embrace all such alterations, modifications, and variations that fall within the spirit and scope of the appended claims. Moreover, the above description of illustrated embodiments of the subject disclosure, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize. Moreover, use of the term “an embodiment” or “one embodiment” throughout is not intended to mean the same embodiment unless specifically described as such.

In particular and in regard to the various functions performed by the above described components, devices, circuits, systems and the like, the terms used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the claimed subject matter. In this regard, it will also be recognized that the innovation includes a system as well as a computer-readable storage medium having computer-executable instructions for performing the acts and/or events of the various methods of the claimed subject matter.

The aforementioned systems/circuits/modules have been described with respect to interaction between several components/blocks. It can be appreciated that such systems/circuits and components/blocks can include those components or specified sub-components, some of the specified components or sub-components, and/or additional components, and according to various permutations and combinations of the foregoing. Sub-components can also be implemented as components communicatively coupled to other components rather than included within parent components (hierarchical). Additionally, it should be noted that one or more components may be combined into a single component providing aggregate functionality or divided into several separate sub-components, and any one or more middle layers, such as a management layer, may be provided to communicatively couple to such sub-components in order to provide integrated functionality. Any components described herein may also interact with one or more other components not specifically described herein but known by those of skill in the art.

In addition, while a particular feature of the subject innovation may have been disclosed with respect to only one of several implementations, such feature may be combined with one or more other features of the other implementations as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

As used in this application, the terms “component,” “module,” “system,” or the like are generally intended to refer to a computer-related entity, either hardware (e.g., a circuit), a combination of hardware and software, software, or an entity related to an operational machine with one or more specific functionalities. For example, a component may be, but is not limited to being, a process running on a processor (e.g., digital signal processor), a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers. Further, a “device” can come in the form of specially designed hardware; generalized hardware made specialized by the execution of software thereon that enables the hardware to perform specific function; software stored on a computer readable medium; or a combination thereof.

Moreover, the words “example” or “exemplary” are used herein to mean serving as an example, instance, or illustration. Any aspect or design described herein as “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Computing devices typically include a variety of media, which can include computer-readable storage media and/or communications media, in which these two terms are used herein differently from one another as follows. Computer-readable storage media can be any available storage media that can be accessed by the computer, is typically of a non-transitory nature, and can include both volatile and nonvolatile media, removable and non-removable media. By way of example, and not limitation, computer-readable storage media can be implemented in connection with any method or technology for storage of information such as computer-readable instructions, program modules, structured data, or unstructured data. Computer-readable storage media can include, but are not limited to, RAM, ROM, EEPROM, flash memory or other memory technology, CD-ROM, digital versatile disk (DVD) or other optical disk storage, magnetic cassettes, magnetic tape, magnetic disk storage or other magnetic storage devices, or other tangible and/or non-transitory media which can be used to store desired information. Computer-readable storage media can be accessed by one or more local or remote computing devices, e.g., via access requests, queries or other data retrieval protocols, for a variety of operations with respect to the information stored by the medium.

On the other hand, communications media typically embody computer-readable instructions, data structures, program modules or other structured or unstructured data in a data signal that can be transitory such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

What is claimed is:

1. A system comprising:
an array of microelectromechanical systems (MEMS) acoustic sensors each configured to detect an object; and
a gesture recognition component configured to recognize a gesture based on a time sequence in which the MEMS acoustic sensors of the array of MEMS acoustic sensors respectively detect the object.

2. The system of claim 1, wherein each MEMS acoustic sensor is configured to detect the object if the object is less than a threshold distance away from the system.

3. The system of claim 1, further comprising:
a timing component configured to determine the time sequence based on entry times and exit times associated with each of the MEMS acoustic sensors of the array of MEMS acoustic sensors detecting the object.

4. The system of claim 3, wherein the timing component is further configured to determine a speed associated with the gesture based on the time sequence.

5. The system of claim 1, wherein the array of MEMS acoustic sensors further comprises a two dimensional array of MEMS microphones comprising a first, second, and third MEMS microphone.

6. The system of claim 1, wherein the gesture recognition component is further configured to generate an instruction to control an operation of the system based on the gesture.

7. The system of claim 1, wherein the gesture recognition component is further configured to detect the gesture as at least one of a horizontal swipe or a vertical swipe based on the time sequence.

8. The system of claim 1, further comprising at least one transmitter configured to generate an acoustic signal for reflection off the object, the at least one transmitter comprising at least one of a MEMS acoustic sensor of the array of MEMS acoustic sensors or a speaker component.

9. The system of claim 1, further comprising:
at least one sensor coupled to the gesture recognition component and comprising a different type of sensor than the array of MEMS acoustic sensors, wherein the gesture recognition component is further configured to recognize the gesture based on the time sequence and input from the at least one sensor.

10. The system of claim 11, further comprising:
a sensor fusion component configured to perform a sensor fusion process to fuse the input from the at least one sensor and input associated with the array of MEMS acoustic sensors.

11. A device comprising:
a two dimensional array of microelectromechanical systems (MEMS) acoustic sensors, wherein each MEMS acoustic sensors of the array of MEMS acoustic sensors is configured to detect entry and exit of an object in a field of detection of each of the MEMS acoustic sensors of the array of MEMS acoustic sensors; and
a processor communicably coupled to the two dimensional array of MEMS acoustic sensors and configured to identify a gesture based on the entries and exits.

12. The device of claim 11, wherein a MEMS acoustic sensors of the two dimensional array of MEMS acoustic sensors is configured to detect entry of the object when the object meets a threshold distance from the MEMS acoustic sensors.

13. The device of claim 11, wherein at least two MEMS acoustic sensors of the two dimensional array of MEMS acoustic sensors comprise different structures, frequency response transfer functions, or sensitivities.

14. The device of claim 11, wherein the processor is further configured to determine a direction associated with the gesture.

15. The device of claim 11, wherein the processor is further configured to:
identify the gesture as a previously not identified gesture stored in a memory; and
store the gesture in the memory.

16. The device of claim 11, wherein at least one MEMS acoustic sensors of the two dimensional array of MEMS acoustic sensors is further configured to generate an ultrasonic signal for reflection off the object.

17. A method for detecting a gesture, comprising:
detecting that a first microelectromechanical systems (MEMS) microphone of an array of MEMS microphones has detected an object during a first period;
detecting that a second MEMS microphone of the array of MEMS microphones has detected the object at a second period; and
recognizing the gesture based on comparison of the first period and the second period.

18. The method of claim 17, wherein recognizing the gesture further comprises recognizing the gesture as at least one of a vertical swipe or a horizontal swipe.

19. The method of claim 17, further comprising:
generating an instruction to control a function a device based on the gesture.

20. The method of claim 17, further comprising:
detecting that a third MEMS microphone of the array of MEMS microphones has detected the object at a third period, and wherein the recognizing the gesture further comprises recognizing the gesture based on comparison of the first period, the second period, and the third period.
